(19) United States
(12) Patent Application Publication
(10) Pub. No.: US 2012/0325292 A1
(43) Pub. Date: Dec. 27, 2012

(54) SOLAR CELL MODULE, BACK SHEET STRUCTURE THEREOF AND MANUFACTURING METHOD THEREOF

(75) Inventors: Kuan-Kuo Lai, Bade City (TW); Wei-Chih Huang, New Taipei City (TW)

(73) Assignee: BENQ MATERIALS CORP., Gueishan Township (TW)

(21) Appl. No.: 13/277,681

(22) Filed: Oct. 20, 2011

(30) Foreign Application Priority Data
Jun. 23, 2011 (TW) 100122040

(51) Int. Cl. H01L 31/048; C09J 7/02; B32B 37/12; B32B 27/40

(52) U.S. Cl. 136/251; 428/354; 428/336; 156/329

(57) ABSTRACT

A solar cell module, a back sheet structure thereof and a manufacturing method thereof are provided. The back sheet structure includes a bottom adhesive layer, an insulating layer, a moisture barrier layer and a weather-resistant layer. The bottom adhesive layer is formed by materials including a polyurethane material and a silane material. The silane material amounts to 0.5-1.5% of the weight of the bottom adhesive layer. The insulating layer is disposed on the bottom adhesive layer. The moisture barrier layer is disposed on the insulating layer. The weather-resistant layer is disposed on the moisture barrier layer.

This application claims the benefit of Taiwan application Serial No. 100122040, filed Jun. 23, 2011, the subject matter of which is incorporated herein by reference.

### BACKGROUND OF THE INVENTION

1. Field of the Invention

The invention relates in general to a cell module, a back sheet structure thereof and a manufacturing method thereof, and more particularly to a solar cell module and a back sheet structure thereof and a manufacturing method thereof.

2. Description of the Related Art

As the industries are booming, the demand for power soars up accordingly, and various ways of power generation such as thermal power, hydraulic power and nuclear power are thus provided. Considering the factors that thermal power adds to greenhouse effect, hydraulic power is restricted by the landforms and weather, nuclear power carries the risk of radiation pollution, scientists are dedicated to providing better ways of power generation.

It is predicted that solar power, being free of greenhouse effect, landform restriction and radiation pollution, will be an important source of power in the next generation.

The solar cell module currently provided by the industries performs a lamination process through an EVA layer. The lamination process is an important process of the solar cell module, and takes about 20 to 40 minutes to complete. However, during which time, the double bonds of the EVA layer may be easily damaged and yellowed, and this is indeed a bottleneck to the development of the solar cell industry.

### SUMMARY OF THE INVENTION

The invention is directed to a solar cell module and a back sheet structure thereof and a manufacturing method thereof. The design of a bottom adhesive layer dispenses with the use of EVA layer, hence avoiding the occurrence of yellowing. Furthermore, the laminating process can be adopted to largely increase the process efficiency.

According to an aspect of the present invention, a back sheet structure of a solar cell module is provided. The back sheet structure includes a bottom adhesive layer, an insulating layer, a moisture barrier layer and a weather-resistant layer. The bottom adhesive layer is formed by materials including a polyurethane material and a silane material. The silane material amounts to 0.5-1.5% of the weight of the bottom adhesive layer. The insulating layer is disposed on the bottom adhesive layer. The moisture barrier layer is disposed on the insulating layer. The weather-resistant layer is disposed on the moisture barrier layer.

According to an alternative aspect of the present invention, a solar cell module is provided. The solar cell module includes a photoelectrical conversion structure and a back sheet structure. The back sheet structure includes a bottom adhesive layer, an insulating layer, a moisture barrier layer and a weather-resistant layer. The bottom adhesive layer, directly disposed on the photoelectrical conversion structure, is formed by materials including a polyurethane material and a silane material. The silane material amounts to 0.5-1.5% of the weight of the bottom adhesive layer. The insulating layer is disposed on the bottom adhesive layer. The moisture barrier layer is disposed on the insulating layer. The weather-resistant layer is disposed on the moisture barrier layer.

According to yet another alternative aspect of the present invention, a manufacturing method of a solar cell module is provided. The manufacturing method of a solar cell module includes the following steps. A photoelectrical conversion structure is provided. A back sheet structure including a bottom adhesive layer is provided, wherein the bottom adhesive layer is formed by materials including a polyurethane material and a silane material. The silane material amounts to 0.5-1.5% of the weight of the bottom adhesive layer. The back sheet structure, laminated on the photoelectrical conversion structure by a laminator, directly contacts the photoelectrical conversion structure.

The above and other aspects of the invention will become better understood with regard to the following detailed description of the preferred but non-limiting embodiment (s). The following description is made with reference to the accompanying drawings.

### BRIEF DESCRIPTION OF THE DRAWINGS

FIG. 1 shows a schematic diagram of a solar cell module according to the present embodiment of the invention;

FIG. 2 shows a schematic diagram of a back sheet structure;

FIGS. 3 to 6 respectively flow processes of a manufacturing method of a solar cell module according to the present embodiment of the invention.

### DETAILED DESCRIPTION OF THE INVENTION

An embodiment is disclosed below for detailed descriptions of the invention. Through the design of a bottom adhesive layer, the solar cell module of the present embodiment of the invention dispenses with the use of EVA layer, hence avoiding the occurrence of yellowing. Furthermore, the laminating process can be adopted to largely increase the process efficiency. However, the embodiments are for exemplification purpose only, not for limiting the scope of protection of the invention. In addition, in the embodiments, a part of the elements are omitted to highlight the technical features of the invention.

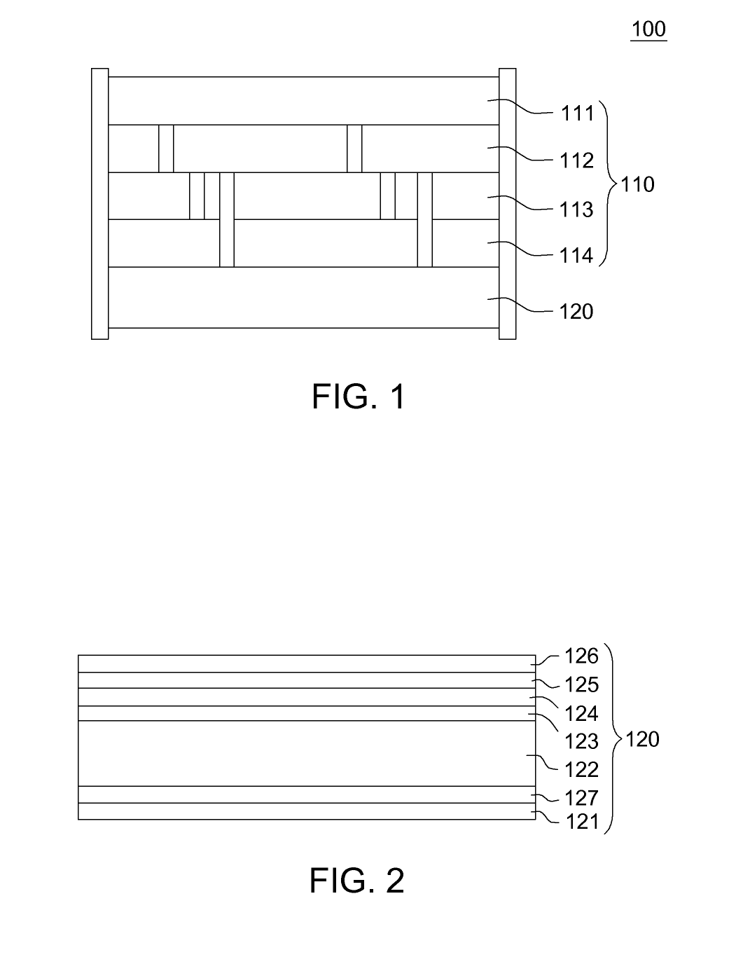

Referring to FIG. 1, a schematic diagram of a solar cell module 100 according to the present embodiment of the invention is shown. The solar cell module 100 includes a photoelectrical conversion structure 110 and a back sheet structure 120. The photoelectrical conversion structure 110 absorbs an external solar light, and further converts the external solar light into electrical energy. The back sheet structure 120 carries and protects the photoelectrical conversion structure 110.

The photoelectrical conversion structure 110 is provided with a glass layer 111, a transparent conductive oxide (TCO) layer 112, an a-Si layer 113 and a back electrode layer 114 wherein the glass layer 111, the TCO layer 112, the a-Si layer 113 and the back electrode layer 114 are stacked in sequence.

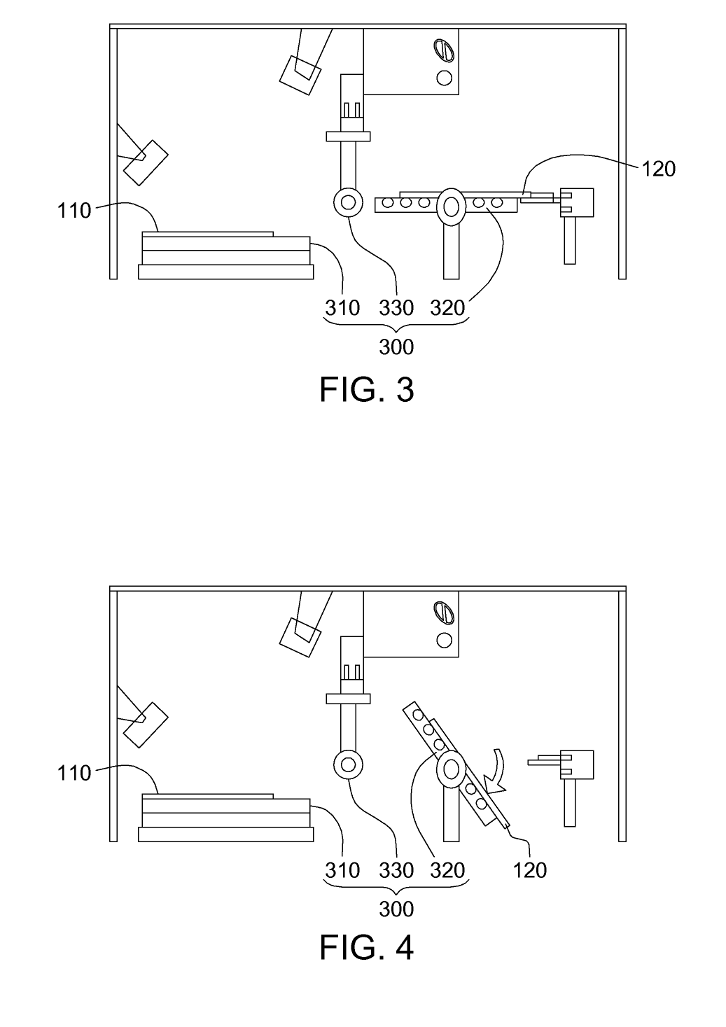

Referring to FIG. 2, a schematic diagram of a back sheet structure 120 is shown. The back sheet structure 120 includes a release film 121, a bottom adhesive layer 127, an insulating layer 122, a moisture barrier layer 124 and a weather-resistant layer 126. The bottom adhesive layer 127 is formed by materials including a polyurethane material and a silane material, wherein the silane material amounts to 0.5 to 1.5% of the weight of the bottom adhesive layer. The insulating layer 122 is realized by such as a PET film. The moisture barrier layer 124 is realized by such as an aluminum film. The weather-resistant layer 126 is realized by such as a fluorine film.

The bottom adhesive layer 127 is directly disposed on the photoelectrical conversion structure 110. That is, the adhesion between the back sheet structure 120 and the photoelectrical conversion structure 110 is implemented by a bottom adhesive layer 127 instead of an EVA layer.

The insulating layer 122 is disposed on the bottom adhesive layer 127. The moisture barrier layer 124 is disposed on the insulating layer 122. The weather-resistant layer 126 is disposed on the moisture barrier layer 124. The insulating layer 122, the moisture barrier layer 124 and the weather-resistant layer 126 are stacked sequentially through the adhesive layer 123 between the insulating layer 122 and the moisture barrier 124 and through the adhesive layer 125 between the moisture barrier layer 124 and weather-resistant layer 126 to form a back sheet structure 120. Before the back sheet 120 is used, the back sheet 120 can be adhered on the release film 121 through the bottom adhesive layer 127.

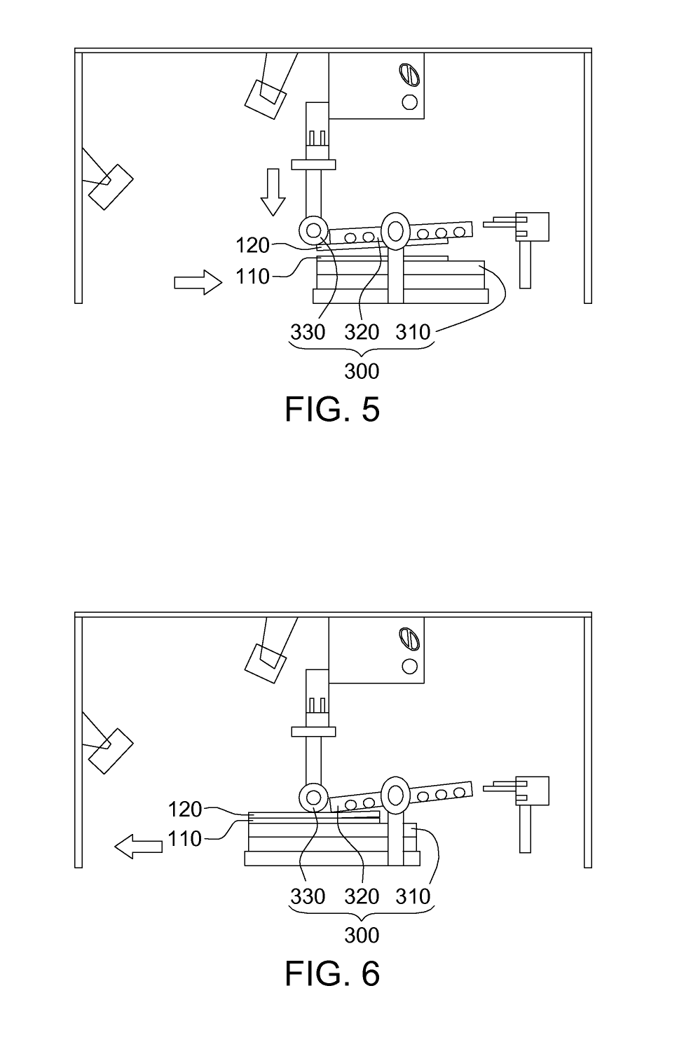

Referring to FIGS. 3 to 6, flow processes of a manufacturing method of a solar cell module 100 according to the present embodiment of the invention are respectively shown. The design of the bottom adhesive layer 127 adopted in the present embodiment of the invention brings dramatic change to the manufacturing method of the solar cell module 100, in which the laminating technology is adopted to increase the process speed.

Firstly, as indicated in FIG. 3, a photoelectrical conversion structure 110 is provided on a carrying platform 310 of a laminator 300.

Next as indicated in FIG. 3, a back sheet structure 120 is provided on a suspension arm 320 of the laminator 300.

Then, as indicated in FIG. 4, the back sheet structure 120 is turned over by the suspension arm 320.

Then, as indicated in FIGS. 5 to 6, the back sheet structure 120 and the photoelectrical conversion structure 110 are pressed by a roller 330 to make the back sheet structure 120 laminated on the photoelectrical conversion structure 110. Thus, the process of bonding the back sheet structure 120 and the photoelectrical conversion structure 110 together is completed.

The present embodiment of the invention adopts the design of the bottom adhesive layer 127 of the back sheet structure 120, so that the solar cell module 100, which can dispense with the use of EVA layer, can be manufactured by the laminating technology. The process of the laminating technology does not require the heating process which takes 20 to 40 minutes, and can be completed within 1 minute, largely shortening the processing time.

In terms of the material of the silane of the bottom adhesive layer 127, the silane material, generally referred as coupling agent or silane coupling agent, is used as a bridging agent between an inorganic material (such as glass) and an organic resin. The functional group of the silane material is selected from a group consists of amino group, vinyl group, epoxy group, methacrylic group, diamino group, thiol group and a combination thereof.

In terms of the material of the polyurethane of the bottom adhesive layer 127, the polyurethane material can further include a cross-linking agent (containing a NCO functional base) to achieve cross-linking. The polyurethane material is a solvent type resin, wherein the solid content of solvent can be adjusted according to the equipment status, so that the adhesion after cross-linking achieved ranges from 1000 to 50 cps, the molecular weight Mw is controlled to be within the range from 1500000 to 2000000, and the molecular weight Mw before cross-linking is controlled to be 10000.

In terms of thickness, the thickness of the weather-resistant layer 126 ranges from 20 to 30 μm, the thickness of the moisture barrier layer 124 ranges from 15 to 25 μm, the thickness of the insulating layer 122 ranges from 180 to 200 μm, and the thickness of the bottom adhesive layer 127 ranges from 20 to 25 μm.

In a preferred embodiment of the invention, the back sheet comprising of the 25 μm weather-resistant layer 126, the 10 μm adhesive layers 125, the 20 μm aluminum moisture barrier layer 124, the 10 μm adhesive layer 123, the 190 μm insulating layer 122, the 25 μm bottom adhesive layer 127, and the 15 μm release film 121 was prepared for experiment. After the release film 121 is removed, the total effective thickness is 280 μm, and the area for each layer is 15 cm×15 cm.

The process for manufacturing the bottom adhesive layer 127 is as follows. Firstly, 100 g of LIS-73 colloid manufactured by the Toyo Ink Co., Ltd. are used, wherein the solid content amounts to 35%.

Next, 42.85 g of solvent such as ethyl acetate (EAC) are added to the LIS-73 colloid to make dilution wherein the weight percentage is about 65% (or, 60 to 75%). The colloid can also be diluted by butanone (MEK) or isopropyl alcohol (IPA).

Then, the DYNAGRAND CR-001 hardener manufactured by the Toyo Ink Co., Ltd. is added to the colloid wherein the hardener is about 10 g, and amount to about 10% (or 5 to 15%) of the weight of the colloid before any solvent is added thereto.

Then, the 3-(2,3-epoxypropoxy)propyltrimethoxysilane (GLYMO) manufactured by the Vulchem Company is added to the colloid dilution, wherein the silane is about 1.4 g, and amounts to about 1% (or 0.5 to 1.5%) of the weight of the colloid dilution.

Then, the colloid dilution is coated on the insulating layer 122 of the back sheet structure and heated in a dryer, wherein, the coating method is such as bar coating. The coated back sheet structure 120 is placed in a dryer under the temperature of 80° C. for 3 minutes, then the back sheet structure 120 is removed and placed in a 40° C. environment with 55% relative humidity for 7 days to proceed aging process.

After the back sheet structure 120 is laminated on the photoelectrical conversion structure 110, various tests can be conducted accordingly.

In the adhesion test, experimental samples are prepared and a peeling force testing machine is set according to the ASTM D-903 specifications. The experimental test shows that the peeling force of the experimental samples can reach 10.96N/cm.

The reliability test (RA) such as the highly accelerated temperature and humidity stress test (HAST) is conducted for 300 hours according to the IEC60068-2-66 specifications. The test shows that the above experimental samples are free of delamination and bubbles, and the appearance of the back sheet does not deteriorate either, and it is concluded that the experimental samples are conformed to the IEC61646 standards.

In the power reliability test, the power loss after the reliability test is about 3.86%, and is conformed to the IEC61646 standards.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A back sheet structure of a solar cell module, comprising:
a bottom adhesive layer formed by materials comprising a polyurethane material and a silane material, wherein the silane material amounts to 0.5-1.5% of the weight of the bottom adhesive layer;
an insulating layer disposed on the bottom adhesive layer;
a moisture barrier layer disposed on the insulating layer; and
a weather-resistant layer disposed on the moisture barrier layer.

2. The back sheet structure according to claim 1, wherein the thickness of the bottom adhesive layer ranges between 20 to 25 μm.

3. The back sheet structure according to claim 1, wherein the functional group of the silane material is selected from a group consists of amino group, vinyl group, epoxy group, methacrylic group, diamino group, thiol group and a combination thereof.

4. The back sheet structure according to claim 1, wherein the molecular weight of the polyurethane material ranges from 1500000 to 2000000.

5. A solar cell module, comprising:
a photoelectrical conversion structure; and
a back sheet structure, comprising:
a bottom adhesive layer directly disposed on the photoelectrical conversion structure and formed by materials comprising a polyurethane material and a silane material, wherein the silane material amounts to 0.5-1.5% of the weight of the bottom adhesive layer;
an insulating layer disposed on the bottom adhesive layer;
a moisture barrier layer disposed on the insulating layer; and
a weather-resistant layer disposed on the moisture barrier layer.

6. The solar cell module according to claim 5, wherein the thickness of the bottom adhesive layer ranges from 20 to 25 μm.

7. The solar cell module according to claim 5, wherein the functional group of the silane material is selected from a group consists of amino group, vinyl group, epoxy group, methacrylic group, diamino group, thiol group and a combination thereof.

8. The solar cell module according to claim 5, wherein the molecular weight of the polyurethane material ranges from 1500000 to 2000000.

9. A manufacturing method of a solar cell module, comprising:
providing a photoelectrical conversion structure;
providing a back sheet structure, wherein the back sheet structure comprises a bottom adhesive layer, the bottom adhesive layer is formed by materials comprising a polyurethane material and a silane material, and the silane material amounts to 0.5-1.5% of the weight of the bottom adhesive layer; and
laminating a back sheet structure on the photoelectrical conversion structure by a laminator, wherein the bottom adhesive layer directly contacts the photoelectrical conversion structure.
